(19) United States
(12) Patent Application Publication
(10) Pub. No.: US 2026/0198287 A1
(43) Pub. Date: Jul. 9, 2026

(54) BACK-SIDE POWER RAIL DEVICE AND METHOD OF MAKING SAME

(71) Applicant: TAIWAN SEMICONDUCTOR MANUFACTURING COMPANY, LTD., Hsinchu (TW)

(72) Inventors: Yung-Shih CHENG, Hsinchu (TW); Wei Tse HSU, Hsinchu (TW); Liang-Guang CHEN, Hsinchu (TW); Fu-Ming HUANG, Changhua (TW)

(21) Appl. No.: 19/011,680

(22) Filed: Jan. 7, 2025

(51) Int. Cl. H01L 23/528; H01L 23/522; H01L 23/532

(52) U.S. Cl. CPC H10W 20/427; H10W 20/42; H10W 20/435; H10W 20/4403

(57) ABSTRACT

A method of forming a back-side power rail device includes forming a device layer over a front-side of a substrate, forming, over the device layer, a front-side interconnect layer that includes a first interconnect structure, a metal region, and a guarding dummy structure laterally between the first interconnect structure and the metal region, forming a first dielectric layer over the front-side interconnect layer, removing, from a back-side of the substrate, at least a portion of the substrate to expose the device layer, forming one or more back-side vias coupled with the device layer opposite the front-side interconnect layer, forming a second interconnect structure over the device layer and the one or more back-side vias, and forming one or more conductive features over the second interconnect structure.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a perspective view at an initial stage of manufacturing a semiconductor device structure, in accordance with some embodiments.

FIG. 2 is a perspective view of another stage of manufacturing the semiconductor device structure, in accordance with some embodiments.

FIGS. 3A-3B are section views, that correspond to an X cut along line A-A in FIGS. 1-2, of another stage of manufacturing the semiconductor device structure, in accordance with some embodiments.

FIGS. 4A-4D are top section views, of a portion of a semiconductor device structure that corresponds to the inset of FIG. 3B, that illustrate various layouts of a guarding dummy structure, in accordance with some embodiments.

FIGS. 4E-4F are top section views of a portion of a different semiconductor device structure that includes a low metal density region, in accordance with some embodiments.

FIGS. 5A-5B are section views, that correspond to FIGS. 3A-3B, respectively, of another stage of manufacturing the semiconductor device structure, in accordance with some embodiments.

FIGS. 6A-6B are section views, that correspond to FIGS. 5A-5B, respectively, of another stage of manufacturing the semiconductor device structure, in accordance with some embodiments.

FIGS. 7A-7B are section views, that correspond to FIGS. 6A-6B, respectively, of another stage of manufacturing the semiconductor device structure, in accordance with some embodiments.

FIGS. 8A-8B are section views, that correspond to FIGS. 7A-7B, respectively, of another stage of manufacturing the semiconductor device structure, in accordance with some embodiments.

FIGS. 9A-9B are section views, that correspond to FIGS. 8A-8B, respectively, of another stage of manufacturing the semiconductor device structure, in accordance with some embodiments.

FIG. 10 is a section view, that corresponds to FIG. 9A, of another stage of manufacturing the semiconductor device structure, in accordance with some embodiments.

FIG. 11 is a diagrammatic section view that illustrates a back-side power rail device, in accordance with some embodiments.

FIG. 12 is a diagrammatic top view that illustrates a die that includes a semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure provide a semiconductor device structure and method that includes a guarding dummy structure within the semiconductor device structure to counteract tensile stress release caused by a metal region (e.g., high metal density region), thereby preventing detrimental effects on device performance. For example, the guarding dummy structure can prevent, or reduce, source/drain pattern shift of nearby device regions. Furthermore, the guarding dummy structure can improve overlay of back-side vias to epitaxial source/drain regions, which can prevent, or reduce, open circuits between back-side vias and the epitaxial source/drain regions, and/or short circuits between back-side vias and gate structures.

While the embodiments of this disclosure are discussed with respect to nanostructure channel FETs, such as gate all around (GAA) FETs, for example Horizontal Gate All Around (HGAA) FETs or Vertical Gate All Around (VGAA) FETs, implementations of some aspects of the present disclosure may be used in other processes and/or in other devices, such as planar FETs, Fin-FETs, and other suitable devices. A person having ordinary skill in the art will readily understand other modifications that may be made are contemplated within the scope of this disclosure. In cases where gate all around (GAA) transistor structures are adapted, the GAA transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

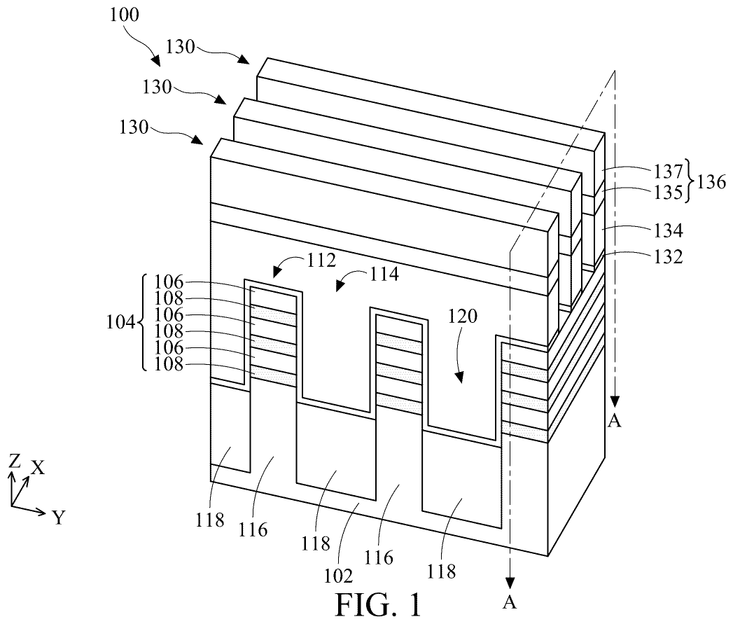

FIGS. 1-12 show exemplary processes for manufacturing a semiconductor device structure 100 according to embodiments of the present disclosure. It is understood that additional operations can be provided before, during, and after processes shown by FIGS. 1-12 , and some of the operations described below can be replaced or eliminated, for additional embodiments of the method. The order of the operations/processes is not limiting and may be interchangeable.

FIG. 1 is a perspective view at an initial stage of manufacturing a semiconductor device structure 100, in accordance with some embodiments. As shown in FIG. 1, a semiconductor device structure 100 includes a stack of semiconductor layers 104 formed over a front side of a substrate 102. The substrate 102 may be a semiconductor substrate. The substrate 102 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In some embodiments, the substrate 102 is a silicon-on-insulator (SOI) substrate having an insulating layer (not shown) disposed between two silicon layers for enhancement. In one aspect, the insulating layer is an oxygen-containing layer.

The substrate 102 may include various regions that have been doped with impurities (e.g., dopants having p-type or n-type conductivity). Depending on circuit design, the dopants may be, for example phosphorus for an n-type field effect transistors (NFET) and boron for a p-type field effect transistors (PFET).

The stack of semiconductor layers 104 includes alternating semiconductor layers made of different materials to facilitate formation of nanostructure channels in a multi-gate device, such as nanostructure channel FETs. In some embodiments, the stack of semiconductor layers 104 includes first semiconductor layers 106 and second semiconductor layers 108. In some embodiments, the stack of semiconductor layers 104 includes alternating first and second semiconductor layers 106, 108. The first semiconductor layers 106 and the second semiconductor layers 108 are made of semiconductor materials having different etch selectivity and/or oxidation rates. For example, the first semiconductor layers 106 may be made of Si and the second semiconductor layers 108 may be made of SiGe. In some examples, the first semiconductor layers 106 may be made of SiGe and the second semiconductor layers 108 may be made of Si. Alternatively, in some embodiments, either of the semiconductor layers 106, 108 may be or include other materials such as Ge, SiC, GeAs, GaP, InP, InAs, InSb, GaAsP, AlInAs, AlGaAs, InGaAs, GaInP, GaInAsP, or any combinations thereof.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

The first semiconductor layers 106 or portions thereof may form nanostructure channel(s) of the semiconductor device structure 100 in later fabrication stages. The term nanostructure is used herein to designate any material portion with nanoscale, or even microscale dimensions, and having an elongate shape, regardless of the cross-sectional shape of this portion. Thus, this term designates both circular and substantially circular cross-section elongate material portions, and beam or bar-shaped material portions including, for example, a cylindrical in shape or substantially rectangular cross-section. The nanostructure channel(s) of the semiconductor device structure 100 may be surrounded by a gate electrode. The semiconductor device structure 100 may include a nanostructure transistor. The nanostructure transistors may be referred to as nanosheet transistors, nanowire transistors, gate-all-around (GAA) transistors, multi-bridge channel (MBC) transistors, or any transistors having the gate electrode surrounding the channels. The use of the first semiconductor layers 106 to define a channel or channels of the semiconductor device structure 100 is further discussed below.

Each first semiconductor layer 106 may have a thickness in a range between about 5 nm and about 30 nm. Each second semiconductor layer 108 may have a thickness that is equal, less, or greater than the thickness of the first semiconductor layer 106. In some embodiments, each second semiconductor layer 108 has a thickness in a range between about 2 nm and about 50 nm. Three first semiconductor layers 106 and three second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104, and the number of layers depending on the predetermined number of channels for the semiconductor device structure 100. In some embodiments, the stack of semiconductor layers 104 includes two first semiconductor layers 106. In some embodiments, the stack of semiconductor layers 104 includes three first semiconductor layers 106. In some embodiments, the stack of semiconductor layers 104 includes four first semiconductor layers 106.

As shown in FIG. 1, fin structures 112 are formed from the stack of semiconductor layers 104. Each fin structure 112 has an upper portion including the semiconductor layers 106, 108 and a well portion 116 formed from the substrate 102. The fin structures 112 may be formed by patterning a hard mask layer (not shown) formed on the stack of semiconductor layers 104 using multi-patterning operations including photo-lithography and etching processes. The etching process can include dry etching, wet etching, reactive ion etching (RIE), and/or other suitable processes. The photo-lithography process may include forming a photoresist layer (not shown) over the hard mask layer, exposing the photoresist layer to a pattern, performing post-exposure bake processes, and developing the photoresist layer to form a masking element including the photoresist layer. In some embodiments, patterning the photoresist layer to form the masking element may be performed using an electron beam (e-beam) lithography process. The etching process forms trenches 114 in unprotected regions through the hard mask layer, through the stack of semiconductor layers 104, and into the substrate 102, thereby leaving the plurality of extending fin structures 112. The trenches 114 extend along the X direction. The trenches 114 may be etched using a dry etch (e.g., RIE), a wet etch, and/or combination thereof.

As shown in FIG. 1, after the fin structures 112 are formed, an insulating material 118 is formed on the substrate 102. The insulating material 118 fills the trenches 114 between neighboring fin structures 112 until the fin structures 112 are embedded in the insulating material 118. Then, a planarization operation, such as a chemical mechanical polishing (CMP) method and/or an etch-back method, is performed such that the top of the fin structures 112 is exposed. The insulating material 118 may be made of silicon oxide, silicon nitride, silicon oxynitride (SiON), SiOCN, SiCN, fluorine-doped silicate glass (FSG), a low-K dielectric material, or any suitable dielectric material. The insulating material 118 may be formed by any suitable method, such as low-pressure chemical vapor deposition (LPCVD), plasma enhanced CVD (PECVD) or flowable CVD (FCVD).

As shown in FIG. 1, the insulating material 118 is recessed to form isolation regions 120. The recess of the insulating material 118 exposes portions of the fin structures 112, such as the stack of semiconductor layers 104. The recess of the insulating material 118 reveals the trenches 114 between the neighboring fin structures 112. The isolation regions 120 may be formed using a suitable process, such as a dry etching process, a wet etching process, or a combination thereof. A top surface of the insulating material 118 may be level with or below a surface of the second semiconductor layers 108 in contact with the well portion 116 formed from the substrate 102. In some embodiments, the isolation regions 120 are the shallow trench isolation (STI) regions.

As shown in FIG. 1, one or more sacrificial gate structures 130 (three are shown) are formed over the semiconductor device structure 100. The sacrificial gate structures 130 are formed over a portion of the fin structures 112. Each sacrificial gate structure 130 may include a sacrificial gate dielectric layer 132, a sacrificial gate electrode layer 134, and a mask layer 136. The sacrificial gate dielectric layer 132, the sacrificial gate electrode layer 134, and the mask layer 136 may be formed by sequentially depositing blanket layers of the sacrificial gate dielectric layer 132, the sacrificial gate electrode layer 134, and the mask layer 136, and then patterning those layers into the sacrificial gate structures 130. While one sacrificial gate structure 130 is shown, two or more sacrificial gate structures 130 may be arranged along the X direction in some embodiments.

The sacrificial gate dielectric layer 132 may include one or more layers of dielectric material, such as a silicon oxide-based material. The sacrificial gate electrode layer 134 may include silicon such as polycrystalline silicon or amorphous silicon. The mask layer 136 may include more than one layer, such as an oxide layer 135 and a nitride layer 137. The portions of the fin structures 112 that are covered by the sacrificial gate electrode layer 134 of the sacrificial gate structure 130 serve as channel regions for the semiconductor device structure 100.

FIG. 2 is a perspective view of another stage of manufacturing the semiconductor device structure 100, in accordance with some embodiments. In FIG. 2, a spacer layer 140 is formed over (e.g., covering) the sacrificial gate structures 130, exposed portions of the fin structures 112, and exposed portions of the insulating layer 118. The spacer layer 140 may include one or more layers of dielectric material, such as silicon oxide, silicon nitride, silicon carbide, silicon oxynitride, SiCN, silicon oxycarbide, SiOCN, and/or combinations thereof. In some embodiments, the spacer layer 140 includes two dielectric layers. In some embodiments, the spacer layer 140 is formed by a conformal process, such as an atomic layer deposition (ALD) process. In some embodiments, the spacer layer 140 has a thickness ranging from about 2 nm to about 10 nm.

An anisotropic etch process is performed to remove horizontal portions of the spacer layer 140. The anisotropic etch process may be a selective etch process that does not substantially affect the nitride layer 137, the first semiconductor layer 106, and the insulating layer 118. As a result, portions of the fin structures 112, apart from regions covered by vertical portions of the spacer layer 140, are exposed.

One or more etch processes are performed to recess the exposed portions of the fin structures 112 that are not covered by the sacrificial gate structures 130 (and the portions of the spacer layer 140 formed on sidewalls of the sacrificial gate structures 130) and to remove portions of the spacer layer 140. In some embodiments, portions of the spacer layer 140 formed on sidewalls of the mask layer 136 also may be recessed. The one or more etch processes may include a dry etch, such as reactive ion etching, neutral beam etching (NBE), or the like, and/or a wet etch, such as using tetramethylammonium hydroxide (TMAH), or ammonium hydroxide (NH₄OH). The one or more etch processes form spacer layers 140 including first portions formed on sidewalls of the sacrificial gate electrode layer 134 and second portions formed on portions of the insulating layer 118.

Edge portions of each second semiconductor layer 108 of the stack of semiconductor layers 104 are removed horizontally along the X-direction. The removal of the edge portions of the second semiconductor layers 108 forms cavities between adjoining first semiconductor layers 106 that are above and below the second semiconductor layers 108. In some embodiments, the portions of the second semiconductor layers 108 are removed by a selective wet etch process. In embodiments where the second semiconductor layers 108 are made of SiGe and the first semiconductor layers 106 are made of silicon, the second semiconductor layers 108 can be selectively etched using a wet etchant such as, but not limited to, ammonium hydroxide (NH₄OH), tetramethylammonium hydroxide (TMAH), ethylenediamine pyrocatechol (EDP), or potassium hydroxide (KOH) solutions.

After removing edge portions of each second semiconductor layer 108, a dielectric layer is deposited in the cavities to form dielectric spacers 144. The dielectric spacers 144 may be made of a low-K dielectric material, such as SiON, SiCN, SiOC, SiOCN, or SiN. The dielectric spacers 144 may be formed by first forming a conformal dielectric layer using a conformal deposition process, such as ALD, followed by an anisotropic etching to remove portions of the conformal dielectric layer other than the dielectric spacers 144. The dielectric spacers 144 are protected, from etching, by the first semiconductor layers 106 during the anisotropic etching process. The remaining second semiconductor layers 108 are capped between the dielectric spacers 144 along the X-direction.

Epitaxial source/drain (S/D) regions 146 are formed from the well portion 116 (e.g., formed on respective top surfaces of the well portion 116). The epitaxial source/drain regions 146 may grow both vertically and horizontally to form facets, which may correspond to crystalline planes of the material of the well portion 116. In this disclosure, a source region and a drain region are interchangeably used, and the structures thereof are substantially the same. Furthermore, source/drain region(s) may refer to a source or a drain, individually or collectively, dependent upon the context. The epitaxial source/drain regions 146 may be made of one or more layers of Si, SiP, SiC and SiCP for n-type FETs (NFETs) or Si, SiGe, and Ge for p-type FETs (PFETs). For PFETs, p-type dopants, such as boron (B), may also be included in the epitaxial source/drain regions 146. The epitaxial source/drain regions 146 may be formed by an epitaxial growth method using CVD, ALD or MBE.

A contact etch stop layer (CESL) 162 is conformally formed on the exposed surfaces of the semiconductor device structure 100. The CESL 162 covers the sidewalls of the spacer layers 140 and is disposed on the second portion of the spacer layers 140 and the epitaxial source/drain regions 146. The CESL 162 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be formed by CVD, PECVD, ALD, or any suitable deposition technique. Next, a first interlayer dielectric (ILD) layer 164 is formed on the CESL 162. The materials for the first ILD layer 164 may include compounds including Si, O, C, and/or H, such as an oxide, such silicon oxide, SiCOH, or SiOC. Organic materials, such as polymers, may also be used for the first ILD layer 164. The first ILD layer 164 may be deposited by a PECVD process or other suitable deposition technique. In some embodiments, after formation of the first ILD layer 164, the semiconductor device structure 100 may be subject to a thermal process to anneal the first ILD layer 164.

A planarization process is performed to expose the sacrificial gate electrode layer 134. The planarization process may be any suitable process, such as a CMP process. The planarization process removes portions of the first ILD layer 164 and the CESL 162 disposed on the sacrificial gate structures 130. The planarization process may also remove the mask layer 136.

The sacrificial gate electrode layer 134 and the sacrificial gate dielectric layer 132 are removed, exposing a portion of the top surface of the topmost first semiconductor layer 106. The first portions of the insulating layer 118 are also exposed. The sacrificial gate electrode layer 134 may be first removed by any suitable process, such as dry etch, wet etch, or a combination thereof, followed by the removal of the sacrificial gate dielectric layer 132, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 134 but not the spacer layers 140, the insulating layer 118, the first ILD layer 164, and the CESL 162.

After removing the sacrificial gate electrode layer 134 and the sacrificial gate dielectric layer 132, the second semiconductor layers 108 may be removed using a selective wet etching process. In embodiments where the second semiconductor layers 108 are made of SiGe and the first semiconductor layers 106 are made of Si, the chemistry used in the selective wet etching process removes the SiGe while not substantially affecting Si, the dielectric materials of the spacer layers 140, the insulating layer 118, and the dielectric spacers 144. In one embodiment, the second semiconductor layers 108 can be removed using a wet etchant such as, but not limited to, hydrofluoric acid (HF), nitric acid (HNO₃), hydrochloric acid (HCl), phosphoric acid (H₃PO₄), a dry etchant such as fluorine-based (e.g., F₂) or chlorine-based (e.g., Cl₂) gas, or any suitable isotropic etchants.

After removing the second semiconductor layers 108 to form nanostructure channels (i.e., the exposed portions of the first semiconductor layers 106), a gate dielectric layer 170 is formed to surround the exposed portions of the first semiconductor layers 106, and a gate electrode layer 172 is formed on the gate dielectric layer 170. The gate dielectric layer 170 and the gate electrode layer 172 may be collectively referred to as a gate structure 174. In some embodiments, the gate dielectric layer 170 includes one or more layers of a dielectric material, such as silicon oxide, silicon nitride, or high-K dielectric material, other suitable dielectric material, and/or combinations thereof. Examples of high-K dielectric materials include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. The gate dielectric layer 170 may be formed by CVD, ALD or any suitable deposition technique. The gate electrode layer 172 may include one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or any combinations thereof. The gate electrode layer 172 may be formed by CVD, ALD, electro-plating, or other suitable deposition techniques. The gate dielectric layer 170 and the gate electrode layer 172 also may be deposited over the first ILD layer 164. The gate dielectric layer 170 and the gate electrode layer 172 formed over the first ILD layer 164 are then removed by using, for example, CMP, until the top surface of the first ILD layer 164 is exposed.

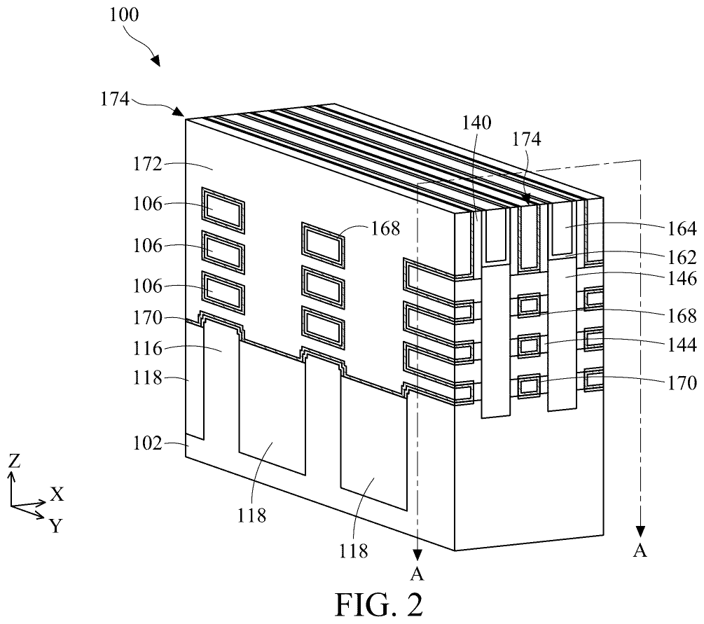

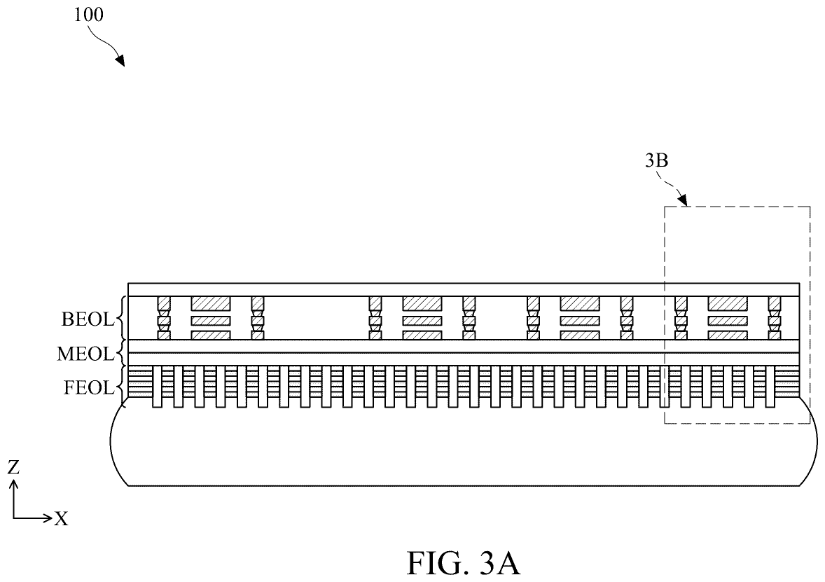

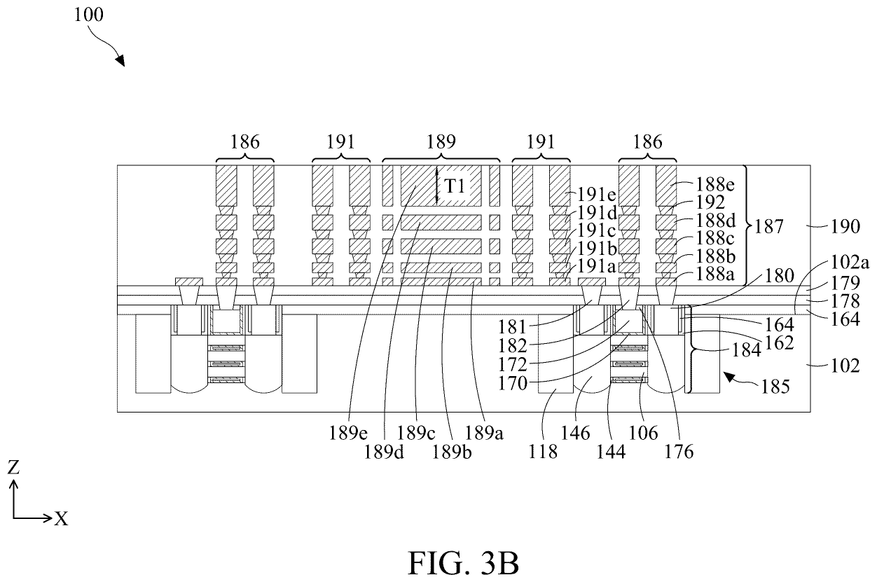

FIGS. 3A-3B are section views that correspond to an X cut along line A-A in FIGS. 1-2, of another stage of manufacturing the semiconductor device structure 100, in accordance with some embodiments. FIG. 3A includes a section view of the entire semiconductor device structure 100 and FIG. 3B further includes an inset (corresponding to the dashed line in FIG. 3A) that illustrates a portion of the semiconductor device structure 100 in greater detail. The section view of the entire semiconductor device structure 100 in FIG. 3A is shown to provide additional context, whereas most details and reference numerals that follow are intended to be understood in connection with the inset of FIG. 3B. With reference to FIG. 3A, portions of the semiconductor device structure 100 correspond to either front end of line (FEOL), middle end of line (MEOL), or back end of line (BEOL), as these terms are generally understood in the art. The semiconductor device structure 100 includes a plurality of transistor structures, which are spaced apart laterally (along both the X-direction and Y-direction). While only a pair of the transistor structures are illustrated in the inset of FIG. 3B, the following description is intended to apply to suitable features of the entire semiconductor device structure 100 without limitation.

Continuing from the description provided above in connection with FIG. 2, in FIG. 3B, the gate structures 174 (including the gate dielectric layers 170 and the corresponding overlying gate electrode layers 172) are recessed, so that recesses are formed directly over the gate structures 174 and between opposing portions of dielectric spacers 144. Gate masks 176 comprising one or more layers of dielectric material, such as silicon nitride, silicon oxynitride, or the like, are filled in the recesses, followed by a planarization process to remove excess portions of the dielectric material extending over the first ILD layer 164. Subsequently formed gate contacts (such as the gate contacts 182, discussed below) penetrate through the gate masks 176 to contact the top surfaces of the recessed gate electrode layers 172.

An etch stop layer 178 is deposited over the first ILD layer 164 and over the gate masks 176. In some embodiments, the etch stop layer 178 is formed of a dielectric material such as SiN, PSG, BSG, BPSG, USG, or the like, and may be deposited by any suitable method, such as CVD, PECVD, or the like. In some embodiments, a second ILD layer 179 is deposited over the etch stop layer 178. In some embodiments, the second ILD layer 179 is a flowable film formed by FCVD. In some embodiments, the second ILD layer 179 is formed of a dielectric material such as PSG, BSG, BPSG, USG, or the like, and may be deposited by any suitable method, such as CVD, PECVD, or the like.

The second ILD layer 179, the first ILD layer 164, the CESL 162, and the gate masks 176 are etched to form recesses exposing surfaces of the epitaxial source/drain regions 146 and/or the gate structures. The recesses may be formed by etching using an anisotropic etching process, such as RIE, NBE, or the like. In some embodiments, the recesses may be etched through the second ILD layer 179 and the first ILD layer 164 using a first etching process; may be etched through the gate masks 176 using a second etching process; and may then be etched through the CESL 162 using a third etching process. A mask, such as a photoresist, may be formed and patterned over the second ILD layer 179 to mask portions of the second ILD layer 179 from the first etching process and the second etching process. In some embodiments, the etching process may over-etch, and therefore, the recesses extend into the epitaxial source/drain regions 146 and/or the gate structures, and a bottom of the recesses may be level with (e.g., at a same level, or having a same distance from the substrate 102), or lower than (e.g., closer to the substrate 102) the epitaxial source/drain regions 146 and/or the gate structures. Although certain figures may illustrate exposing the epitaxial source/drain regions 146 and the gate structures in a same cross-section, in various embodiments, the epitaxial source/drain regions 146 and the gate structures may be exposed in different cross-sections, thereby reducing the risk of shorting subsequently formed contacts.

After the recesses are formed, source/drain contacts 180 and gate contacts 182 (also referred to as contact plugs) are formed in the recesses. Forming the source/drain contacts 180 can include formation of silicide regions over the epitaxial source/drain regions 146. In some embodiments, the silicide regions are formed by first depositing a metal capable of reacting with the semiconductor materials of the underlying epitaxial source/drain regions 146 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 146, then performing a thermal anneal process to form the silicide regions. The un-reacted portions of the deposited metal are then removed, e.g., by an etching process. Although the silicide regions are referred to as silicide regions, the silicide regions may also be germanide regions, or silicon germanide regions (e.g., regions comprising silicide and germanide). In some embodiments, the silicide regions comprise TiSi and have a thickness in a range between about 2 nm and about 10 nm.

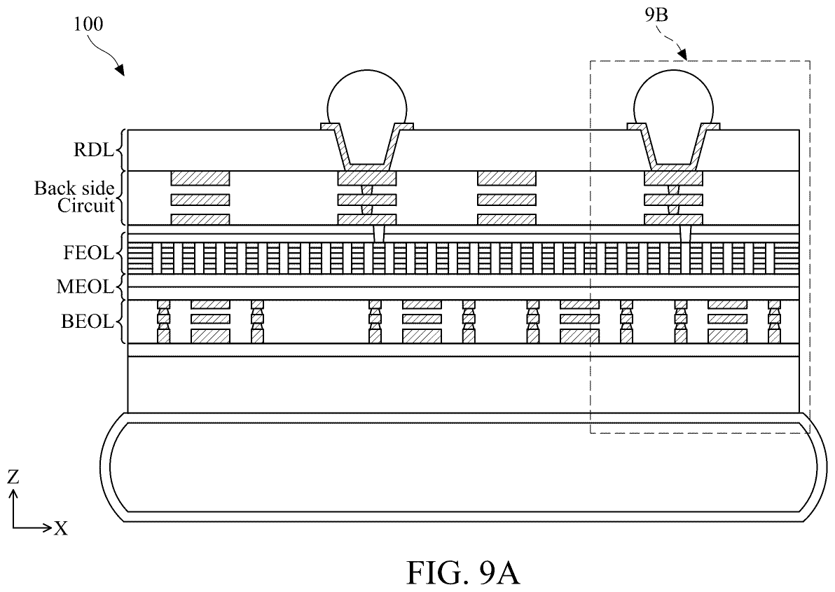

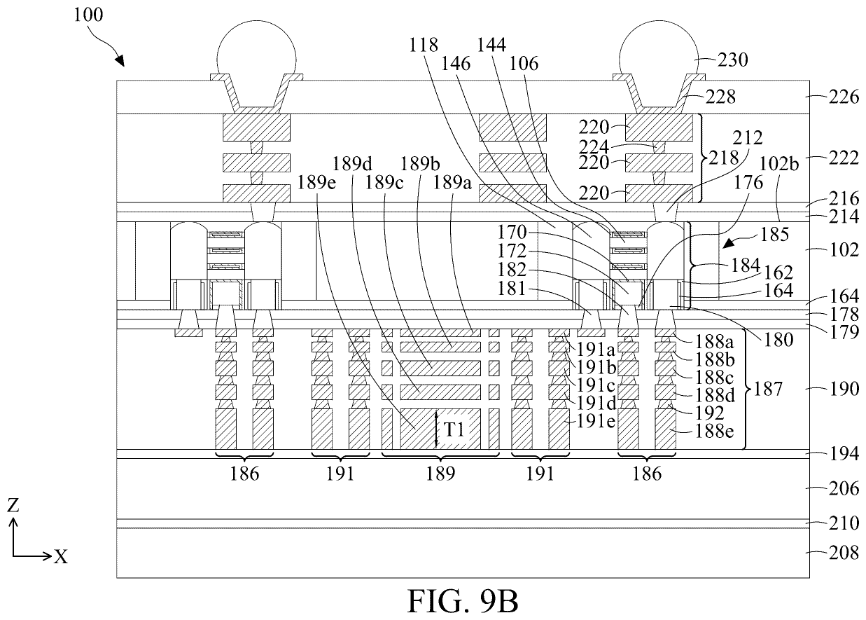

The source/drain contacts 180 and the gate contacts 182 may each comprise one or more layers, such as barrier layers, diffusion layers, and fill materials. For example, in some embodiments, the source/drain contacts 180 and the gate contacts 182 each include a barrier layer and a conductive material and are each electrically coupled to an underlying conductive feature (e.g., a gate electrode layer 172 and/or a silicide region). The gate contacts 182 are electrically coupled to the gate electrode layers 172 and the source/drain contacts 180 are electrically coupled to the silicide regions. In some embodiments, the source/drain contacts 180 can include a conductive contact and a source/drain via 181 formed over the conductive contact. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from surfaces of the second ILD layer 179. The epitaxial source/drain regions 146, the first semiconductor layers 106, and the gate structures 174 (including the gate dielectric layers 170 and the gate electrode layers 172) may be referred to, collectively, as transistor structures 184. The transistor structures 184 may be formed in a device layer 185, with a first interconnect structure (such as the front-side interconnect structure 186, discussed below with respect to FIG. 3B) being formed over a front-side thereof and a second interconnect structure (such as the back-side interconnect structure 218, discussed below with respect to FIGS. 9A-9B) being formed over a back-side thereof. Although the device layer 185 is described as having nano-FETs, other embodiments may include a device layer having different types of transistors (e.g., planar FETs, FinFETs, thin film transistors (TFTs), or the like).

Although FIG. 3B illustrates a source/drain contact 180 extending to each of the epitaxial source/drain regions 146, the source/drain contacts 180 may be omitted from certain ones of the epitaxial source/drain regions 146. For example, as explained in greater detail below, conductive features (e.g., back-side vias or power rails) may be subsequently attached through a back-side of one or more of the epitaxial source/drain regions 146. For these particular epitaxial source/drain regions 146, the source/drain contacts 180 may be omitted or may be dummy contacts that are not electrically connected to any overlying conductive lines (such as the high metal density region 189, discussed below with respect to FIG. 3B).

The present application describes forming front-side interconnect structures and backside interconnect structures on the transistor structures 184. The front-side and back-side interconnect structures may each comprise conductive features that are electrically connected to the nano-FETs formed on the substrate 102. The process described in connection with each of the front-side and back-side interconnect structures can be applied to both NFETs and PFETs. As noted above and discussed in greater detail below, a back-side conductive feature (e.g., a back-side via or a super power rail (SPR)) may be connected to one or more of the epitaxial source/drain regions 146. As such, the source/drain contacts 180 may be optionally omitted from the epitaxial source/drain regions 146.

A front-side interconnect layer 187 is formed on the second ILD layer 179 and over the device layer 185 (which includes the transistors structures 184). The term “front-side” is used in this context because the device layer 185, and thus the front-side interconnect layer 187, are formed over a front-side 102a of the substrate 102.

The front-side interconnect structure 186 is defined in a certain portion of the front-side interconnect layer 187 as shown in FIG. 3B. The front-side interconnect structure 186 includes one or more layers of first conductive features 188 formed in one or more stacked first dielectric layers 190 and connected by respective front-side vias 192. Each of the stacked first dielectric layers 190 may include a dielectric material, such as a low-k dielectric material, an extra low-k (ELK) dielectric material, or the like. The first dielectric layers 190 may be deposited using an appropriate process, such as, CVD, ALD, PVD, PECVD, or the like.

The first conductive features 188 may comprise conductive lines and conductive vias 192 interconnecting the layers of conductive lines. The conductive vias 192 may extend through respective ones of the first dielectric layers 190 to provide vertical connections between layers of the conductive lines. The first conductive features 188 may be formed through any suitable process, such as, a damascene process, a dual damascene process, or the like.

In some embodiments, the first conductive features 188 may be formed using a damascene process in which a respective first dielectric layer 190 is patterned utilizing a combination of photolithography and etching techniques to form trenches corresponding to the desired pattern of the first conductive features 188. An optional diffusion barrier and/or optional adhesion layer may be deposited and the trenches may then be filled with a conductive material. Suitable materials for the barrier layer include titanium, titanium nitride, titanium oxide, tantalum, tantalum nitride, tantalum oxide, combinations thereof, or the like, and suitable materials for the conductive material include copper, silver, gold, tungsten, aluminum, combinations thereof, or the like. In an embodiment, the first conductive features 188 may be formed by depositing a seed layer of copper or a copper alloy and filling the trenches by electroplating. A chemical mechanical planarization (CMP) process or the like may be used to remove excess conductive material from a surface of the respective first dielectric layer 190 and to planarize surfaces of the first dielectric layer 190 and the first conductive features 188 for subsequent processing.

FIG. 3B illustrates five layers (referred to herein as M0-M4) of the first conductive features 188 and the first dielectric layers 190 in the front-side interconnect structure 186. However, it should be appreciated that the front-side interconnect structure 186 may comprise any number of first conductive features 188, such as 14 layers of first conductive features 188 (e.g., which may be referred to as M0-M13, with M0 being a layer closest to the device layer 185 of transistor structures 184 and M13 being a layer farthest from the device layer 185 of transistor structures 184), disposed in any number of first dielectric layers 190. The front-side interconnect structure 186 may be electrically connected to the gate contacts 182 and the source/drain contacts 180 to form functional circuits. In some embodiments, the functional circuits formed by the front-side interconnect structure 186 may comprise logic circuits, memory circuits, image sensor circuits, input-output (IO) circuits, electrostatic discharge (ESD) protector circuits, metal-oxide-metal (MOM) capacitors, electronic fuses (e-Fuses), or the like. For example, the functional circuits may further include front-side I/O pins, which may be disposed in a topmost first dielectric layer 190 of the front-side interconnect structure 186.

As shown in FIG. 3B, the front-side interconnect layer 187 includes the first interconnect structure 186, a high metal density region 189, and a guarding dummy structure 191 laterally between the first interconnect structure 186 and the high metal density region 189.

The high metal density region 189 is a metal region with a metal density higher than one or more other structures, such as the first interconnect structure 186 and the guarding dummy structure 191. The high metal density region 189 includes first conductive features 189a-e (e.g., a bottommost first conductive feature 189a (the layer closest to the device layer 185 of transistor structures 184), a topmost first conductive feature 189e (the layer farthest from the device layer 185 of transistor structures 184, also referred to herein as “top metal layer”), and a plurality of other first conductive features (e.g., three additional layers (189b-d), but could include more or less layers) in between the bottommost first conductive feature 189a and the topmost first conductive feature 189e. In some embodiments, the first conductive features 189a-e can include metal lines. In some embodiments, the first conductive features 189a-e can include suitable conductive materials such as copper, silver, gold, tungsten, aluminum, combinations thereof, or the like. In some embodiments, the topmost first conductive feature 189e can have a thickness T1 in the Z-direction within a range between 100 nm and 500 nm. In some embodiments, the topmost first conductive feature 189e can have a width in the X-direction greater than 100 nm, such as greater than 500 nm, such as 500 nm to 1000 nm. In some embodiments, the width is above a threshold width (e.g., 500 nm) that can result in certain problems related to the patterning of nearby device regions. In general, the topmost first conductive feature 189e can have high tensile stress (e.g., caused by being above the threshold width and being formed from metal), which when released, can cause the nearby device regions to experience location drift, or what is known in the art as “source/drain pattern shift.” For example, the nearby device regions may move wider apart due to tensile stress release from the high metal density region 189. In some embodiments, the problems arising from the tensile stress release (and corresponding location drift) can include poor overlay of back-side vias to the epitaxial source/drain regions 146, open circuits between back-side vias and the epitaxial source/drain regions 146, and/or short circuits between back-side vias and the gate structures 174. Some proposed solutions to these detrimental effects of tensile stress release on device performance are described in detail below. In particular, embodiments of the present disclosure include the guarding dummy structure 191 that counteracts the tensile stress from the high metal density region 189 and prevents the problems described above.

The first interconnect structure 186 has a lower metal density compared to the high metal density region 189. In some embodiments, a metal density of the first interconnect structure 186 is less than 50% and a metal density of the high metal density region 189 is greater than 50%. In some embodiments, the metal density of the first interconnect structure is between 20% and 40% and the metal density of the high metal density region is greater than 60%, such as between 60% and 80%. In some embodiments, a metal density of the guarding dummy structure 191 is between respective values of metal density for the first interconnect structure 186 and the high metal density region 189. In some embodiments, a metal density of the guarding dummy structure 191 is between 40% and 60%.

In some embodiments, the guarding dummy structure 191 is formed layer by layer simultaneously with the first interconnect structure 186 and the high metal density region 189. The guarding dummy structures 191 may be formed from the same materials as the first interconnect structure 186 and the high metal density region 189, such as copper, silver, gold, tungsten, aluminum, combinations thereof, or the like. Forming the guarding dummy structure 191 includes forming a plurality of guarding dummy layers 191a-e together with and corresponding to respective layers of the high metal density region 189a-e and/or the first interconnect structure 188a-e. For example, a first guarding dummy layer 191a is formed together with and corresponding to a respective first layer 189a of the high metal density region 189 and a respective first layer 188a of the first interconnect structure 186. Thereafter, a first dielectric layer 190 is formed over the first guarding dummy layer 191a, the first layer 189a of the high metal density region 189, and the first layer 188a of the first interconnect structure 186. For example, the first dielectric layer 190 is formed together with and corresponding to a respective first conductive via 192. In some embodiments, the remaining layers of the first interconnect structure 186, the high metal density region 189, and the guarding dummy structure 191 are formed using the same or similar processes until the particular number of layers is formed (e.g., five layers are illustrated in the example of FIG. 3B but any suitable number of layers may be present).

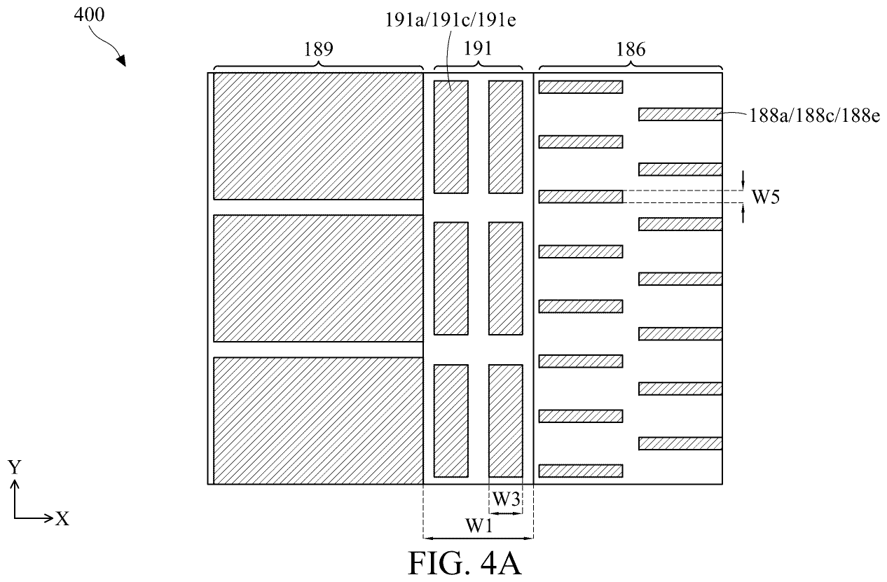

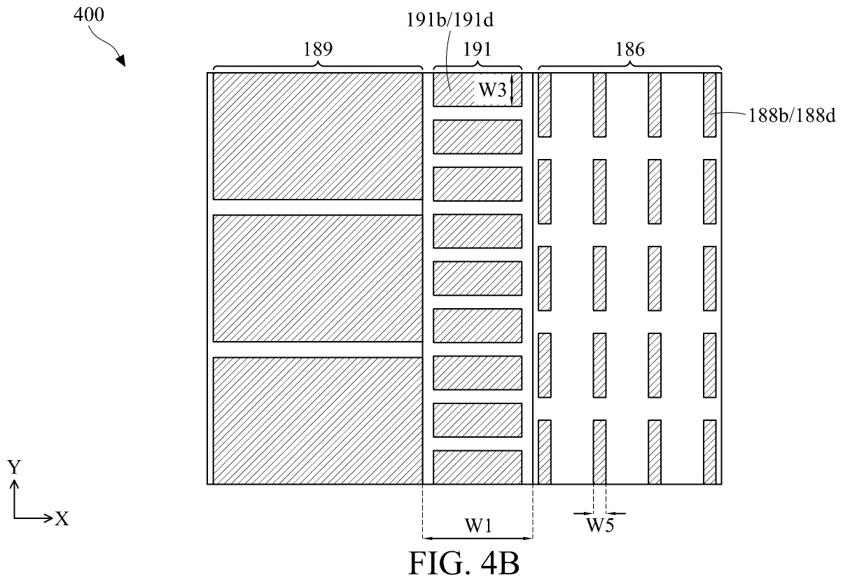

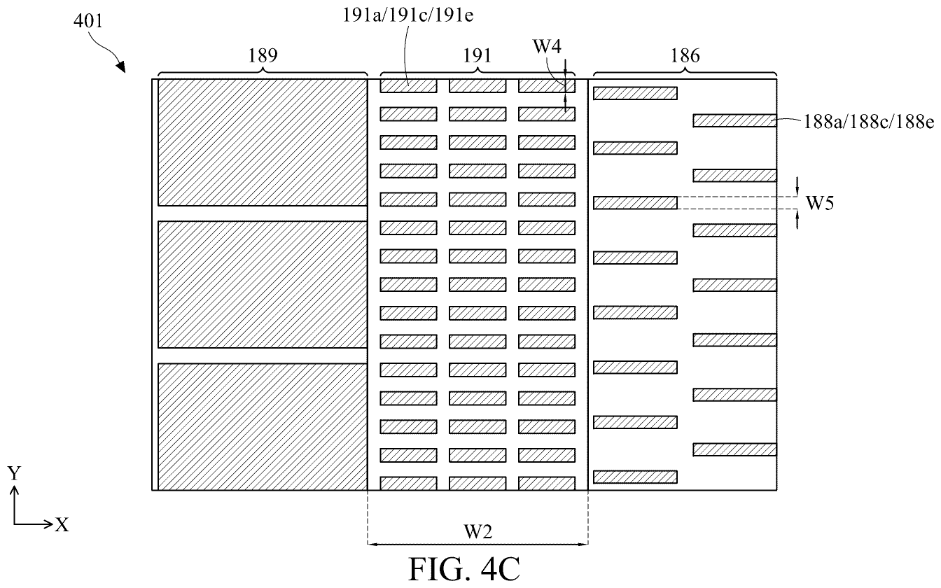

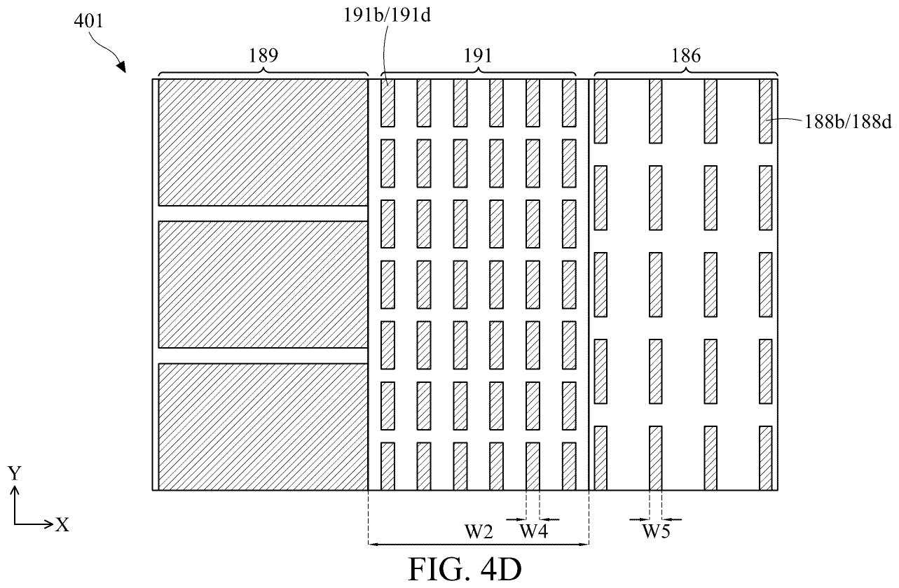

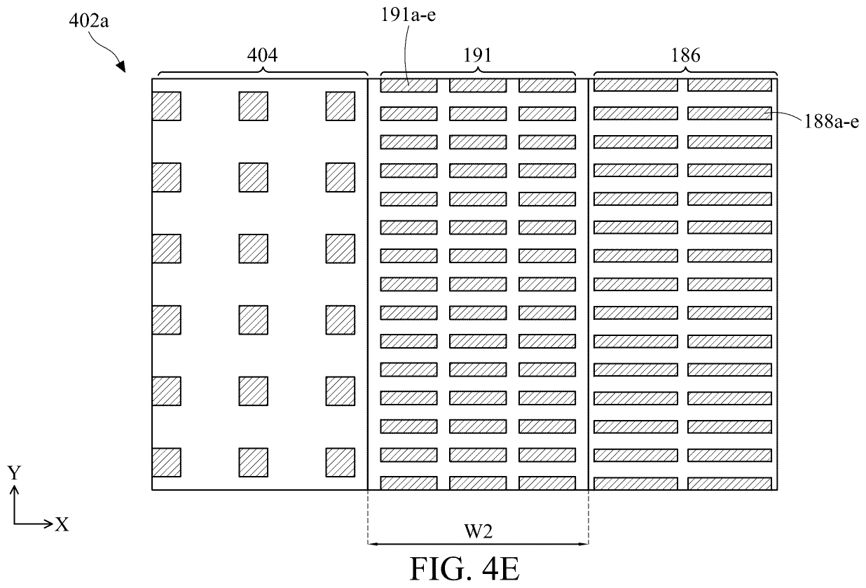

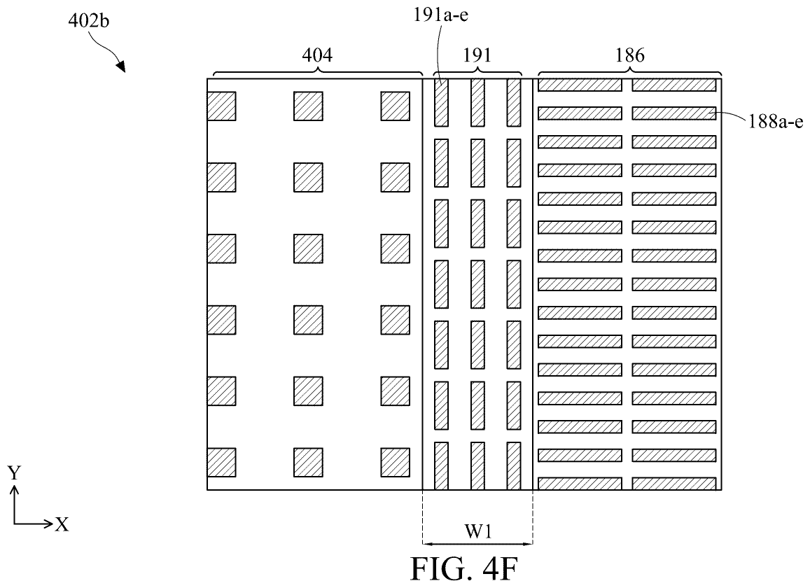

As shown in FIG. 3B, the semiconductor device structure 100 includes a pair of transistor structures 184 with respective overlying first interconnect structures 186 and separate guarding dummy structures 191 on both the left side and right side of the high metal density region 189. However, in some embodiments, only a single guarding dummy structure 191 may be present. Also shown in FIG. 3B, each guarding dummy structure 191 includes two stacks of guarding dummy layers 191a-e that are spaced apart from each other in the X direction (see also FIG. 4A). However, in some embodiments, each guarding dummy structure 191 may include only a single stack (see FIG. 4B) or more than two stacks of guarding dummy layers 191a-e, such as from 3 stacks (see FIG. 4C) to 6 stacks (see FIG. 4D).

FIGS. 4A-4D are top section views, of a portion of the semiconductor device structure 100 that corresponds to the inset of FIG. 3B (i.e., corresponding to the dashed line in FIG. 3A) that illustrate various layouts of the guarding dummy structure 191, in accordance with some embodiments. FIGS. 4A-4B illustrate even metal layers (M0, M2, etc.) and odd metal layers (M1, M3, etc.), respectively, of an exemplary semiconductor device structure 400 where one or more guarding dummy layers 191a-e are oriented lengthwise perpendicular to a lengthwise direction of respective layers 188a-e of the first interconnect structure 186. As used herein, the term “lengthwise” refers to a direction defined parallel to an axis corresponding to the longest dimension of the respective structure. In some embodiments, the one or more guarding dummy layers 191a-e are oriented in a different direction (e.g., opposite or orthogonal direction) from the respective layers 188a-e of the first interconnect structure 186 (e.g., the device layout). For example, in FIG. 4A, which corresponds at least to guarding dummy layers 191a, 191c, and 191e, each guarding dummy layer is oriented lengthwise along the Y direction, whereas the respective layers 188a, 188c, and 188e of the first interconnect structure 186 are oriented along the X direction. Likewise, in FIG. 4B, which corresponds at least to guarding dummy layers 191b and 191d, each guarding dummy layer is oriented lengthwise along the X direction, whereas the respective layers 188b and 188d of the first interconnect structure 186 are oriented along the Y direction. In some embodiments, for example as illustrated in FIGS. 4A-4B, one or more alternating layers 188a-e of the first interconnect structure 186 are oriented lengthwise perpendicular to each other. Likewise, one or more alternating guarding dummy layers 191a-e are oriented lengthwise perpendicular to each other. Therefore, because the guarding dummy layers 191a-e are oriented opposite to the respective layers 188a-e of the first interconnect structure 186 (as described above), the one or more alternating guarding dummy layers 191a-e are oriented lengthwise perpendicular to the respective alternating layers 188a-e of the first interconnect structure 186.

With respect to the even metal layers shown FIG. 4A, the one or more guarding dummy layers 191a, 191c, and 191e are oriented lengthwise perpendicular to a direction between the first interconnect structure 186 and the high metal density region 189. For example, each guarding dummy layer is oriented lengthwise along the Y direction, whereas the direction between the first interconnect structure 186 and the high metal density region 189 is along the X direction. With respect to the odd metal layers shown FIG. 4B, the one or more guarding dummy layers 191b and 191d are oriented lengthwise parallel to the direction between the first interconnect structure 186 and the high metal density region 189. For example, each guarding dummy layer is oriented lengthwise along the X direction, and also the direction between the first interconnect structure 186 and the high metal density region 189 is along the X direction.

FIGS. 4C-4D illustrate even metal layers (M0, M2, etc.) and odd metal layers (M1, M3, etc.), respectively, of a different semiconductor device structure 401 where one or more guarding dummy layers 191a-e are oriented lengthwise parallel to a lengthwise direction of respective layers 188a-e of the first interconnect structure 186. In other words, the one or more guarding dummy layers 191a-e are oriented in the same direction as the respective layers 188a-e of the first interconnect structure 186 (e.g., the device layout). For example, compared to the corresponding guarding dummy layers in FIGS. 4A-4B, these are rotated by 90 degrees. For example, in FIG. 4C, which corresponds at least to guarding dummy layers 191a, 191c, and 191e, each guarding dummy layer is oriented lengthwise along the X direction, and also the respective layers 188a, 188c, and 188e of the first interconnect structure 186 are oriented along the X direction. Likewise, in FIG. 4D, which corresponds at least to guarding dummy layers 191b and 191d, each guarding dummy layer is oriented lengthwise along the Y direction, and also the respective layers 188b and 188d of the first interconnect structure 186 are oriented along the Y direction. In some embodiments, for example as illustrated in FIGS. 4C-4D, one or more alternating layers 188a-e of the first interconnect structure 186 are oriented lengthwise perpendicular to each other. Likewise, one or more alternating guarding dummy layers 191a-e are oriented lengthwise perpendicular to each other. Therefore, because the guarding dummy layers 191a-e are oriented in the same direction as the respective layers 188a-e of the first interconnect structure 186 (as described above), the one or more alternating guarding dummy layers 191a-e are oriented lengthwise parallel to the respective alternating layers 188a-e of the first interconnect structure 186.

With respect to the even metal layers shown FIG. 4C, the one or more guarding dummy layers 191a, 191c, and 191e are oriented lengthwise parallel to the direction between the first interconnect structure 186 and the high metal density region 189. For example, each guarding dummy layer is oriented lengthwise along the X direction, and also the direction between the first interconnect structure 186 and the high metal density region 189 is along the X direction. With respect to the odd metal layers shown FIG. 4D, the one or more guarding dummy layers 191b and 191d are oriented lengthwise perpendicular to the direction between the first interconnect structure 186 and the high metal density region 189. For example, each guarding dummy layer is oriented lengthwise along the Y direction, whereas the direction between the first interconnect structure 186 and the high metal density region 189 is along the X direction.

Comparing the embodiments illustrated in FIGS. 4A-4B and 4C-4D, there is less space (e.g., device area) that is filled by the guarding dummy structure 191 when the one or more guarding dummy layers 191a-e are oriented in a different direction from the respective layers 188a-e of the first interconnect structure 186. For example, a width W1 of the space that is filled by the guarding dummy structure 191 in FIGS. 4A-4B is less than a corresponding width W2 of the same space in FIGS. 4C-4D. In some embodiments, a ratio of the width W1 to the width W2 is 0.9 or less, such as between 0.1 and 0.9, or 0.8 or less, such as between 0.2 and 0.8, or 0.7 or less, such as between 0.3 and 0.7, or 0.6 or less, such as between 0.4 and 0.6, or 0.5 or less, such as 0.5. As a result of the smaller space requirement for the guarding dummy structure 191 in FIGS. 4A-4B, there is a reduction in the total device area and also a reduction in the overall cost of the semiconductor device structure 400 compared to other alternatives.

In some embodiments, a width W3 of each distinct portion of the one or more guarding dummy layers 191a-e in FIGS. 4A-4B is greater than a corresponding width W4 of the same portions in FIGS. 4C-4D. In some embodiments, a ratio of the width W4 to the width W3 is 0.9 or less, such as between 0.1 and 0.9, or 0.8 or less, such as between 0.2 and 0.8, or 0.7 or less, such as between 0.3 and 0.7, or 0.6 or less, such as between 0.4 and 0.6, or 0.5 or less, such as 0.5. As a result of the orientation and/or the width of the one or more guarding dummy layers 191a-e in FIGS. 4A-4B, there can be a reduction in tensile stress release from the high metal density region 189 (as described herein) compared to other alternatives, which can correct one or more problems arising from the tensile stress release (and corresponding location drift) such as poor overlay of back-side vias to the epitaxial source/drain regions 146, open circuits between back-side vias and the epitaxial source/drain regions 146, and/or short circuits between back-side vias and the gate structures 174.

In some embodiments, a width W5 of each respective layer 188a-e of the first interconnect structure 186 can be about the same as the width w4 and/or about half the width W3. The particular widths W1-W5 and associated ratios that are specified herein are understood to provide certain technical advancements in the art, for example, as described above.

FIGS. 4E-4F are top section views, of a portion of a different semiconductor device structure 402a-b that includes a low metal density region 404 in place of the high metal density region 189. The low metal density region 404 can include any suitable features (e.g., materials, dimensions, manufacturing methods, and/or functionality) that are characteristic of the high metal density region 189 as described herein. In some embodiments, a metal density of the low metal density region 404 is less than 35%, whereas the metal density of the high metal density region 189 is at least 50%. In particular, FIGS. 4E-4F illustrate various layouts of the guarding dummy structure 191 in combination with the low metal density region 404, in accordance with some embodiments. In FIGS. 4E-4F, the first interconnect structure 186 has a greater metal density compared to the low metal density region 404. In some embodiments, a metal density of the first interconnect structure 186 is greater than 35% and a metal density of the low metal density region 404 is less than 35%. In some embodiments, the metal density of the first interconnect structure is between 40% and 60% and the metal density of the low metal density region is less than 35%, such as between 20% and 35%. In some embodiments, a metal density of the guarding dummy structure 191 is greater than the metal density of the low metal density region 404. In some embodiments, a metal density of the guarding dummy structure 191 is between 40% and 60%.

As shown in FIG. 4E, the one or more guarding dummy layers 191a-e are oriented lengthwise parallel to a lengthwise direction of respective layers 188a-e of the first interconnect structure 186. In other words, the one or more guarding dummy layers 191a-e are oriented in the same direction as the respective layers 188a-e of the first interconnect structure 186 (e.g., the device layout).

As shown in FIG. 4F, the one or more guarding dummy layers 191a-e are oriented lengthwise perpendicular to a lengthwise direction of respective layers 188a-e of the first interconnect structure 186. In other words, the one or more guarding dummy layers 191a-e are oriented in a different direction as the respective layers 188a-e of the first interconnect structure 186 (e.g., the device layout). Comparing the embodiments illustrated in FIGS. 4E-4F, there is less space (e.g., device area) that is filled by the guarding dummy structure 191 when the one or more guarding dummy layers 191a-e are oriented in a different direction from the respective layers 188a-e of the first interconnect structure 186. For example, a width W1 of the space that is filled by the guarding dummy structure 191 in FIG. 4F is less than a corresponding width W2 of the same space in FIG. 4E. In some embodiments, a ratio of the width W1 to the width W2 is 0.9 or less, such as between 0.1 and 0.9, or 0.8 or less, such as between 0.2 and 0.8, or 0.7 or less, such as between 0.3 and 0.7, or 0.6 or less, such as between 0.4 and 0.6, or 0.5 or less, such as 0.5. As a result of the smaller space requirement for the guarding dummy structure 191 in FIG. 4F, there is a reduction in the total device area and also a reduction in the overall cost of the semiconductor device structure 402b compared to the semiconductor device structure 402a.

As a result of the orientation and/or the width of the one or more guarding dummy layers 191a-e in FIG. 4F, there can be a reduction in tensile stress release caused by a density gradient between the low metal density region 404 and the first interconnect structure 186, which can correct one or more problems arising from the tensile stress release (and corresponding location drift) such as poor overlay of back-side vias to the epitaxial source/drain regions 146, open circuits between back-side vias and the epitaxial source/drain regions 146, and/or short circuits between back-side vias and the gate structures 174.

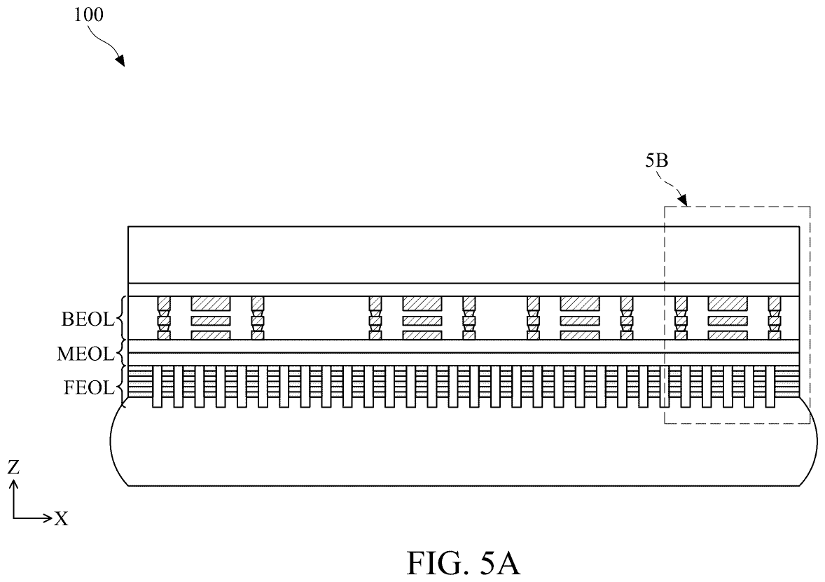

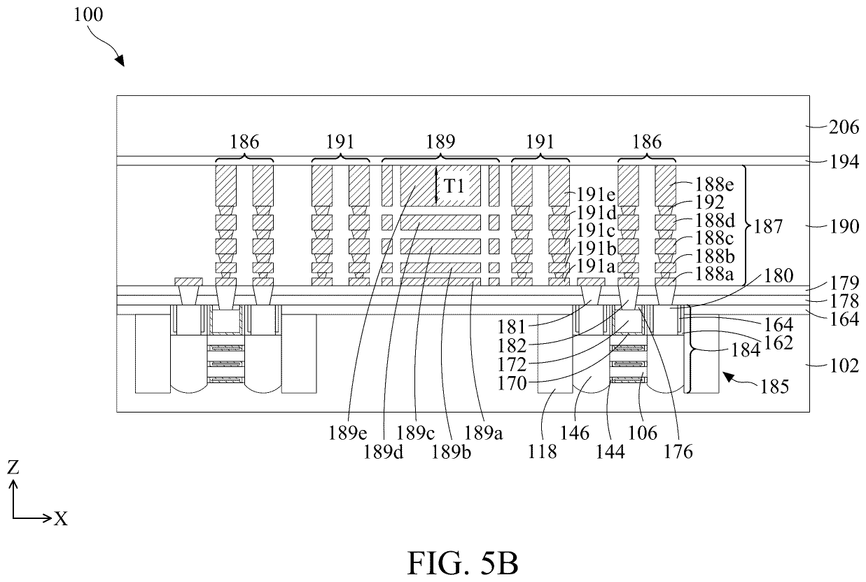

FIGS. 5A-5B are section views, that correspond to FIGS. 3A-3B, respectively, of another stage of manufacturing the semiconductor device structure 100, in accordance with some embodiments. In FIGS. 5A-5B, a second dielectric layer 194 is formed over the first interconnect structure 186. The second dielectric layer 194 may include a dielectric material, such as a low-k dielectric material, an extra low-k (ELK) dielectric material, or the like. The second dielectric layer 194 may be deposited using an appropriate process, such as, CVD, ALD, PVD, PECVD, or the like. In some embodiments, the second dielectric layer 194 is an etch stop layer formed from SiCN. As further shown in FIGS. 5A-5B, a bonding layer 206 is formed over the second dielectric layer 194. The bonding layer 206 includes a dielectric material. In some embodiments, the bonding layer 206 is formed from an oxide material, such as tetraethoxysilane (TEOS) or silicon oxide (SiOx), where x is from 1 to 6. The bonding layer 206 may be deposited using a CVD process, such as HDP-CVD, or any suitable technique. The bonding layer 206 can be thinned to further improve the planarity or flatness of a top surface of the bonding layer 206. The thinning process may include a grinding process, a CMP, an etch-back, combinations thereof, or the like. After the thinning process, a thickness of the bonding layer 206 may be within a range between 100 nm and 1000 nm, such as 250 nm to 750 nm.

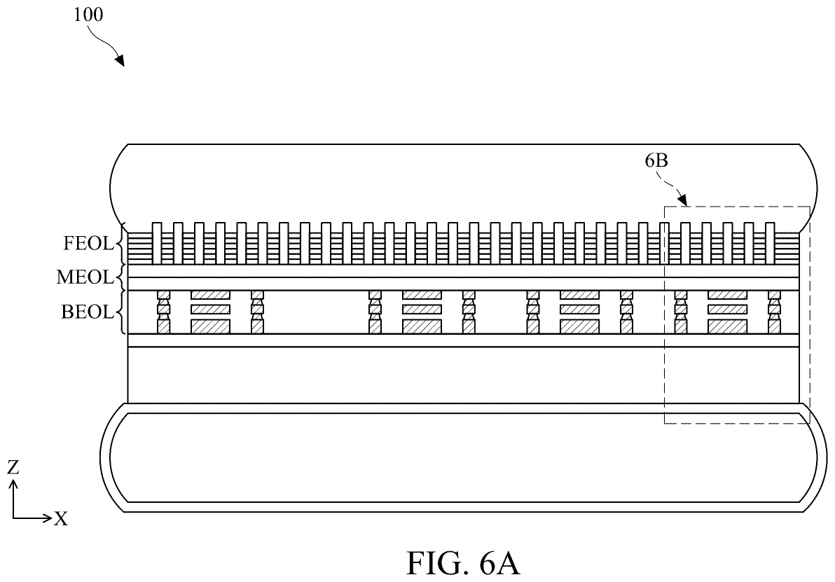

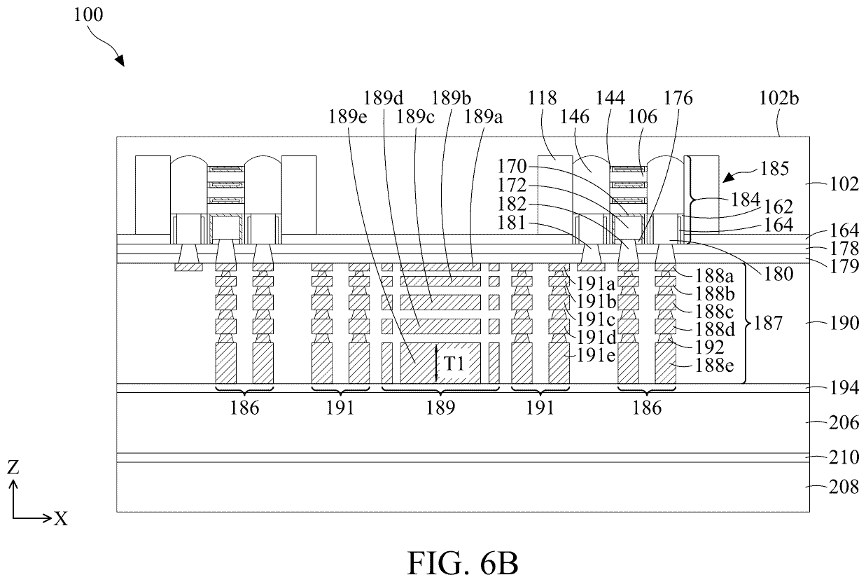

FIGS. 6A-6B are section views that correspond to FIGS. 5A-5B, respectively, of another stage of manufacturing the semiconductor device structure 100, in accordance with some embodiments. In FIGS. 6A-6B, a carrier substrate 208 is bonded with the bonding layer 206, and the semiconductor device structure 100 is flipped so that the carrier substrate 208 is on bottom and the substrate 102 is on top. After the semiconductor device structure 100 is flipped over, the front-side 102a is facing down and the back-side 102b is facing up. The carrier substrate 208 may be a glass carrier substrate, a ceramic carrier substrate, a wafer (e.g., a silicon wafer), or the like. The carrier substrate 208 may provide structural support during subsequent processing steps and in the completed integrated circuit package. In some embodiments, the carrier substrate 208 may be bonded to the front-side interconnect structure 186 (e.g., to the bonding layer 206) using a suitable technique, such as dielectric-to-dielectric bonding, or the like. The dielectric-to-dielectric bonding may optionally include depositing a second bonding layer 210 over a surface of the carrier substrate 208 prior to the bonding. The second bonding layer 210 can include an oxide (e.g., silicon oxide or the like) that is deposited by CVD (e.g., HDP), ALD, PVD, thermal oxidation, or the like. Other suitable materials and processes may be used for the second bonding layer 210.

The dielectric-to-dielectric bonding process may further include applying a surface treatment to one or more of the bonding layer 206 or the second bonding layer 210 (or carrier substrate 208). For example, the surface treatment may include a plasma treatment performed in a vacuum environment. After the plasma treatment, the surface treatment may further include a cleaning process (e.g., a rinse with deionized water or the like) that may be applied to one or more of the bonding layer 206 or the second bonding layer 210 (or carrier substrate 208). The carrier substrate 208 is then aligned with the front-side interconnect structure 186, and the two are pressed against each other to initiate a pre-bonding of the carrier substrate 208 to the front-side interconnect structure 186. In some embodiments, the bonding process causes dangling bonds along the surface of the bonding layer 206 to form chemical bonds with atoms or molecules along the surface of the second bonding layer 210 (or carrier substrate 208), and/or vice versa. As a result, a bonded interface is formed between the bonding layer 206 and the second bonding layer 210 (or carrier substrate 208).

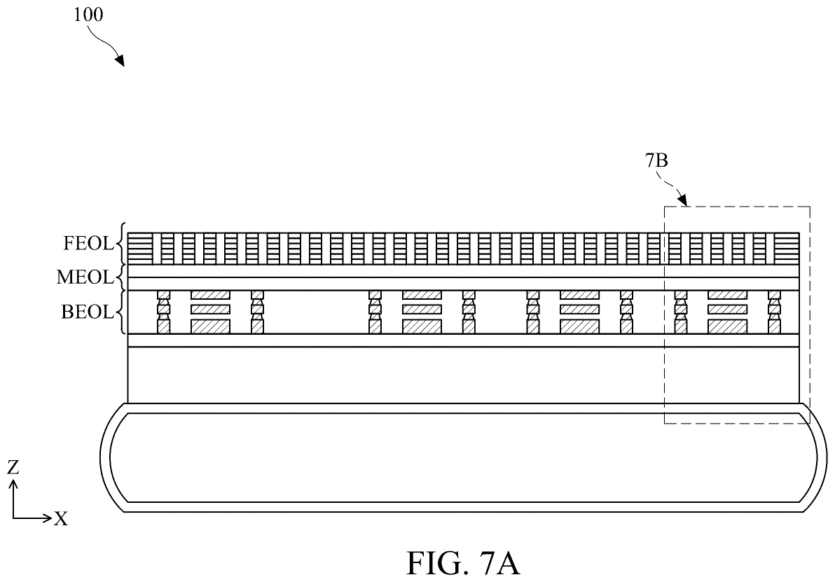

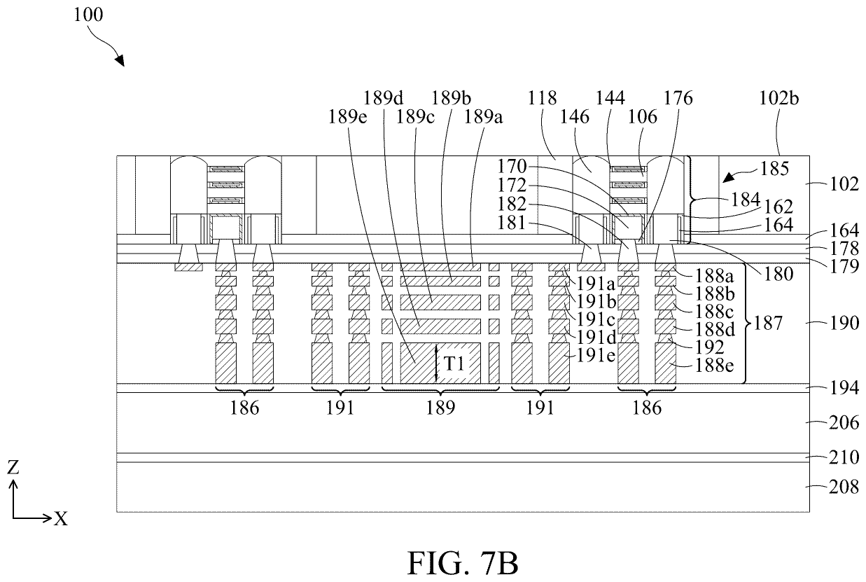

FIGS. 7A-7B are section views that correspond to FIGS. 6A-6B, respectively, of another stage of manufacturing the semiconductor device structure 100, in accordance with some embodiments. In FIGS. 7A-7B, at least a portion of the substrate 102 is removed from the back-side 102b to expose the device layer 185. For example, substrate material may be removed using one or more processes, such as a thinning process, including a grinding process, a CMP, an etch-back, combinations thereof, or the like. In some embodiments, a grinding process or CMP may be performed to remove a majority of the substrate 102 and then followed by a suitable etch-back process to remove either a remainder of the substrate 102 or to form openings in the substrate 102 to expose certain portions of the devices in the device layer 185. In some embodiments, the removal of the portion of the substrate 102 that is described in this section can initiate the tensile stress release of the high metal density region 189 as described above. However, with the addition of the guarding dummy structure 191, certain detrimental effects of the tensile stress release can be prevented, or reduced, as described herein. In some embodiments, a dielectric filling layer, such as SiN, is deposited in the place of the substrate 102. In some embodiments, deposition of the dielectric filling layer is followed by a CMP process.

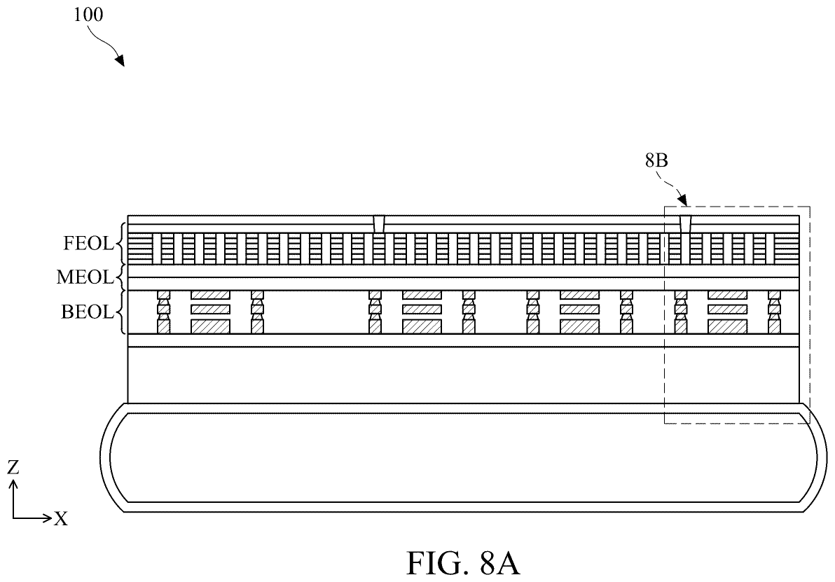

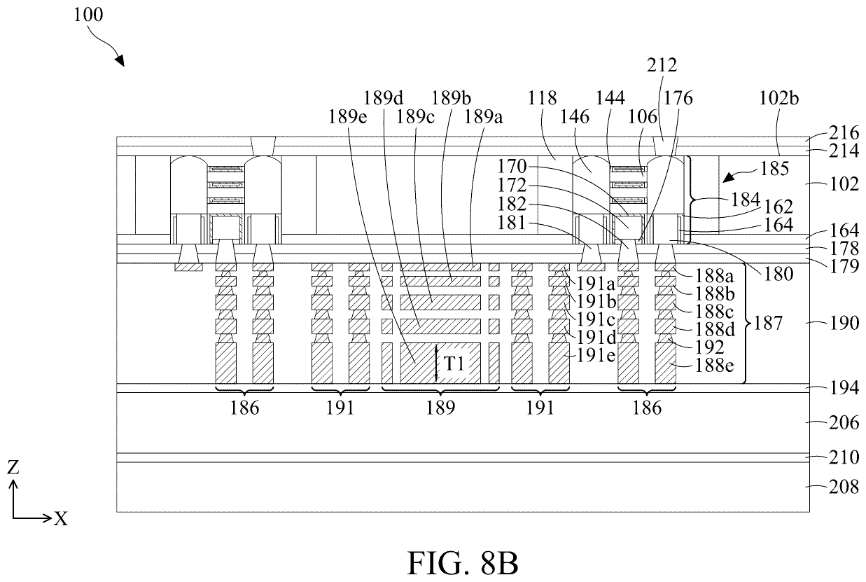

FIGS. 8A-8B are section views that correspond to FIGS. 7A-7B, respectively, of another stage of manufacturing the semiconductor device structure 100, in accordance with some embodiments. In FIGS. 8A-8B, one or more back-side vias 212 are formed to be coupled with the device layer 185 opposite the first interconnect structure 186. For example, two back-side vias are illustrated. Formation of the back-side vias 212 may use a patterning process which can include deposition of one or more other layers, such as ILD layers. For example, the process can include deposition of a fourth ILD layer 214 over the back-side 102b of the substrate 102. In some embodiments, the fourth ILD layer 214 can include compounds including Si, O, C, and/or H, such as an oxide, such as silicon oxide, SiCOH, or SiOC. The fourth ILD layer 214 may be deposited by a PECVD process or other suitable deposition technique. In some embodiments, the process for forming the back-side vias 212 can include deposition of an optional fifth ILD layer 216 over the fourth ILD layer 214. In some embodiments, the fifth ILD layer 216 is a flowable film formed by FCVD. In some embodiments, the fifth ILD layer 216 is formed of a dielectric material such as SiN, PSG, BSG, BPSG, USG, or the like, and may be deposited by any suitable method, such as CVD, PECVD, or the like. In some embodiments, the process for forming the back-side vias 212 can include etching the fourth ILD layer 214 and the fifth ILD layer 216 to form recesses exposing surfaces of the epitaxial source/drain regions 146. The recesses may be formed by etching using an anisotropic etching process, such as RIE, NBE, or the like. A mask, such as a photoresist, may be formed and patterned over the fourth ILD layer 214 and/or fifth ILD layer 216 to mask portions of the respective ILD layer from the etching process. In some embodiments, the etching process may over-etch, and therefore, the recesses extend into the epitaxial source/drain regions 146. After the recesses are formed, the back-side vias 212 are formed in the recesses. Forming the back-side vias 212 can include formation of silicide regions over the epitaxial source/drain regions 146. In some embodiments, the silicide regions are formed by first depositing a metal capable of reacting with the semiconductor materials of the underlying epitaxial source/drain regions 146 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 146, then performing a thermal anneal process to form the silicide regions. The un-reacted portions of the deposited metal are then removed, e.g., by an etching process. Although the silicide regions are referred to as silicide regions, the silicide regions may also be germanide regions, or silicon germanide regions (e.g., regions comprising silicide and germanide). In some embodiments, the silicide regions comprise TiSi and have a thickness in a range between about 2 nm and about 10 nm. The back-side vias 212 may each comprise one or more layers, such as barrier layers, diffusion layers, and fill materials. For example, in some embodiments, the back-side vias 212 each include a barrier layer and a conductive material and are each electrically coupled to an underlying conductive feature (e.g., a silicide region). The back-side vias 212 are electrically coupled to the silicide regions. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from surfaces of the fourth ILD layer 214 or fifth ILD layer 216.

FIGS. 9A-9B are section views, that correspond to FIGS. 8A-8B, respectively, of another stage of manufacturing the semiconductor device structure 100, in accordance with some embodiments. In FIGS. 9A-9B, a back-side interconnect structure 218 is formed over the device layer 185 and the one or more back-side vias 212. The back-side interconnect structure 218 includes one or more layers of second conductive features 220 formed in one or more stacked third dielectric layers 222 and connected by respective vias 224. Each of the stacked third dielectric layers 222 may include a dielectric material, such as a low-k dielectric material, an extra low-k (ELK) dielectric material, or the like. The third dielectric layers 222 may be deposited using an appropriate process, such as, CVD, ALD, PVD, PECVD, or the like.

The second conductive features 220 may comprise conductive lines and conductive vias 224 interconnecting the layers of conductive lines. The conductive vias 224 may extend through respective ones of the third dielectric layers 222 to provide vertical connections between layers of the conductive lines. The second conductive features 220 may be formed through any suitable process, such as, a damascene process, a dual damascene process, or the like. In some embodiments, the second conductive features 220 may be formed using a damascene process in which a respective third dielectric layer 222 is patterned utilizing a combination of photolithography and etching techniques to form trenches corresponding to the desired pattern of the second conductive features 220. An optional diffusion barrier and/or optional adhesion layer may be deposited and the trenches may then be filled with a conductive material. Suitable materials for the barrier layer include titanium, titanium nitride, titanium oxide, tantalum, tantalum nitride, tantalum oxide, combinations thereof, or the like, and suitable materials for the conductive material include copper, silver, gold, tungsten, aluminum, combinations thereof, or the like. In an embodiment, the second conductive features 220 may be formed by depositing a seed layer of copper or a copper alloy and filling the trenches by electroplating. A CMP process or the like may be used to remove excess conductive material from a surface of the respective third dielectric layer 222 and to planarize surfaces of the third dielectric layer 222 and the second conductive features 220 for subsequent processing.

FIG. 9B illustrates three layers of the second conductive features 220 and the third dielectric layers 222 in the back-side interconnect structure 218. However, it should be appreciated that the back-side interconnect structure 218 may comprise any number of second conductive features 220, such as 10 layers of second conductive features 220 (e.g., which may be referred to as M0-M9, with M0 being a layer closest to the device layer 185 of transistor structures 184 and M9 being a layer farthest from the device layer 185 of transistor structures 184), disposed in any number of third dielectric layers 222. The back-side interconnect structure 218 may be electrically connected to the back-side vias 212 to form functional circuits. In some embodiments, the functional circuits formed by the back-side interconnect structure 218 may comprise logic circuits, memory circuits, image sensor circuits, or the like.

The functional circuits may further include a back-side power delivery network (PDN) and/or back-side I/O pins, which may be disposed in a topmost dielectric layer 222 of the back-side interconnect structure 218. The back-side PDN may include back-side power rails. Accordingly, the topmost layer (e.g., the front-side PDN and the back-side pins) of the layers of the second conductive features 220 may be thicker than other layers of the second conductive features 220. In some embodiments, a positive voltage (VDD) may be applied to the back-side PDN. In some embodiments, the back-side PDN may also include conductive lines that are disposed in lower layers of the back-side interconnect structure 218. A thicker topmost PDN layer may include the back-side PDN pins and allow providing a back-side power rail, which benefits from a thick conductive line to handle the power load properly.

In some embodiments, a fourth dielectric layer 226 is formed over the second interconnect structure 218. In some embodiments, one or more third conductive features 228 are formed over the second interconnect structure 218. The one or more third conductive features 228 may be formed in a same layer as the fourth dielectric layer 226. In some embodiments, this layer may be referred to as a “redistribution layer” which can be, or include, a metal layer that enables bond out from different locations on a chip, making chip-to-chip bonding simpler. The one or more third conductive features 228 may be coupled with or include a conductive contact for a back-side power rail. In some embodiments, respective conductive contacts 230 are formed over the one or more third conductive features 228.

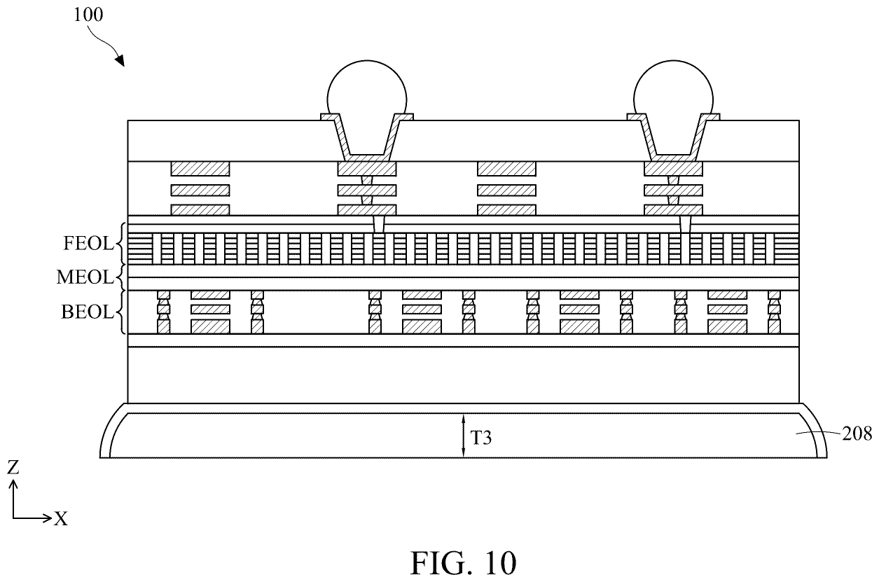

FIG. 10 is a section view, that corresponds to FIG. 9A, of another stage of manufacturing the semiconductor device structure 100, in accordance with some embodiments. In FIG. 10, a portion of the carrier substrate 208 is removed (e.g., using a grinding process) to thin the carrier substrate 208 and/or to ensure exposure of certain features. Removal of the portion of the carrier substrate 208 reduces a thickness T3 of the carrier substrate 208 to within a range between 10 μm and 1000 μm, such as 40 μm to 760 μm. In some embodiments, a dicing process is performed on the semiconductor device structure 100 to form a plurality of dies.

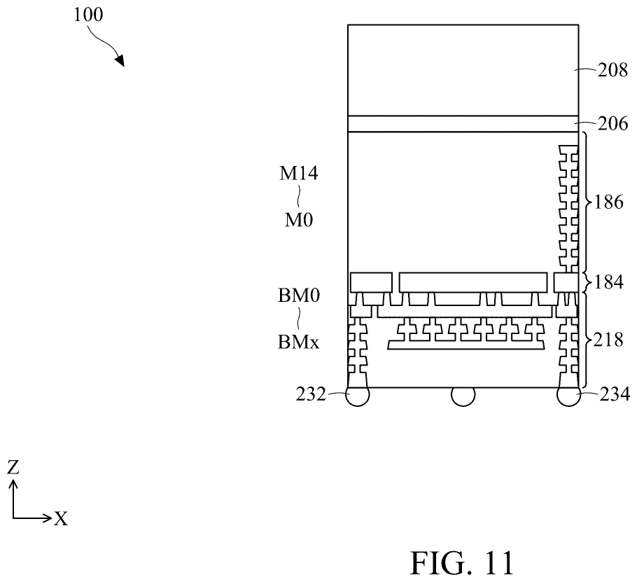

FIG. 11 is a diagrammatic section view that illustrates the semiconductor device structure 100 as a back-side power rail device, in accordance with some embodiments. In FIG. 11, a back-side power rail 232 and back-side I/O pin 234 are coupled with the back-side interconnect structure 218.

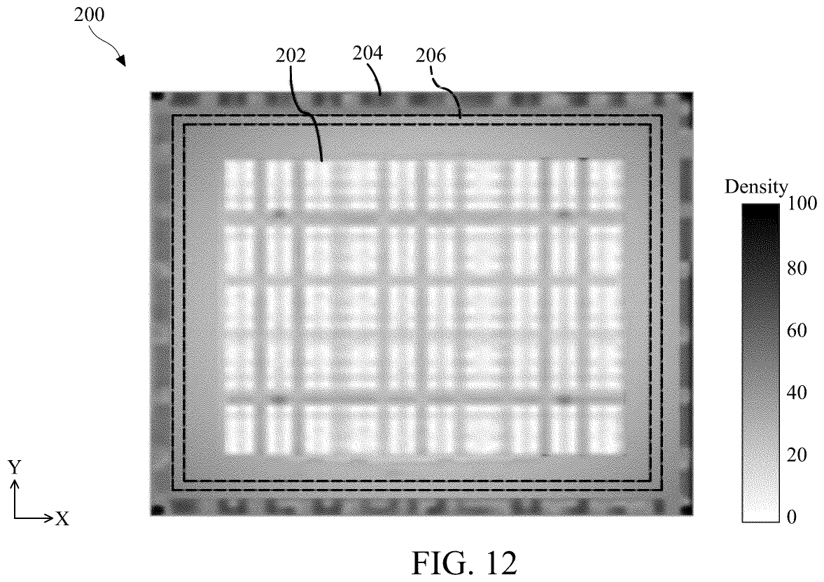

FIG. 12 is a diagrammatic top view that illustrates a die 200 that includes the semiconductor device structure 100, in accordance with some embodiments. As shown in FIG. 12, the die 200 includes a logic circuit 202 defined on an interior portion of the die 200, a periphery circuit 204 defined on a periphery of the die, and a ring portion 206 defined between the interior portion and the periphery portion. In some embodiments, when the semiconductor device structure 100 is formed on the die 200, the first interconnect structure 186 may be associated with the logic circuit 202. In some embodiments, when the semiconductor device structure 100 is formed on the die 200, the high metal density region 189 may be associated with the periphery circuit 204. In some embodiments, when the semiconductor device structure 100 is formed on the die 200, the guarding dummy structure 191 may be associated with the ring portion 206. In some embodiments, the periphery circuit 204 includes at least one of an input-output (IO) circuit, an electrostatic discharge (ESD) protector circuit, a metal-oxide-metal (MOM) capacitor, or an electronic fuse (e-Fuse). FIG. 12 includes a heat map that corresponds to metal density. In some embodiments, the metal density of the logic circuit 202 is between 20% and 40%, the metal density of the periphery circuit is between 60% and 80%, and the metal density of the ring portion is 40% and 60%.

Embodiments of the present disclosure provide a semiconductor device structure and method that embeds a guarding dummy structure 191 within the semiconductor device structure 100 to counteract the tensile stress release caused by the high metal density region 189, thereby preventing the detrimental effects on device performance that are described above. For example, the guarding dummy structure 191 can prevent, or reduce, source/drain pattern shift of nearby device regions. Furthermore, the guarding dummy structure 191 can improve overlay of back-side vias to the epitaxial source/drain regions 146, which can prevent, or reduce, open circuits between back-side vias and the epitaxial source/drain regions 146, and/or short circuits between back-side vias and the gate structures 174.

In some embodiments, a method of forming a back-side power rail device includes forming a device layer over a front-side of a substrate; forming, over the device layer, a front-side interconnect layer that includes: a first interconnect structure, a metal region, and a guarding dummy structure laterally between the first interconnect structure and the metal region; forming a first dielectric layer over the front-side interconnect layer; removing, from a back-side of the substrate, at least a portion of the substrate to expose the device layer; forming one or more back-side vias coupled with the device layer opposite the front-side interconnect layer; forming a second interconnect structure over the device layer and the one or more back-side vias; and forming one or more conductive features over the second interconnect structure.

In some embodiments, a semiconductor device structure includes a device layer disposed over a front-side of a substrate; a front-side interconnect layer disposed over the device layer, the front-side interconnect layer including: a first interconnect structure, a metal region, and a guarding dummy structure laterally between the first interconnect structure and the metal region; a first dielectric layer disposed over the front-side interconnect layer; one or more back-side vias coupled with the device layer opposite the front-side interconnect layer; a second interconnect structure disposed over the device layer and the one or more back-side vias; and one or more conductive features disposed over the second interconnect structure.

In some embodiments, a method of forming a back-side power rail device includes forming a device layer over a front-side of a substrate; forming a first interconnect layer over the device layer, the first interconnect layer including: a first interconnect structure, a metal region, and a guarding dummy structure laterally between the first interconnect structure and the metal region, wherein forming the guarding dummy structure includes forming a plurality of guarding dummy layers together with and corresponding to respective layers of the metal region and the first interconnect structure, wherein the guarding dummy structure is configured to balance a tensile stress of the metal region; forming a first dielectric layer over the first interconnect layer; removing, from a back-side of the substrate, at least a portion of the substrate to expose the device layer; forming one or more back-side vias coupled with the device layer opposite the first interconnect layer; and forming a second interconnect structure over the device layer and the one or more back-side vias to be coupled with a back-side power rail.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method of forming a back-side power rail device, comprising:
forming a device layer over a front-side of a substrate;
forming, over the device layer, a front-side interconnect layer that includes:
a first interconnect structure,
a metal region, and
a guarding dummy structure laterally between the first interconnect structure and the metal region;
forming a first dielectric layer over the front-side interconnect layer;
removing, from a back-side of the substrate, at least a portion of the substrate to expose the device layer;
forming one or more back-side vias coupled with the device layer opposite the front-side interconnect layer;
forming a second interconnect structure over the device layer and the one or more back-side vias; and
forming one or more conductive features over the second interconnect structure.

2. The method of claim 1, wherein a metal density of the guarding dummy structure is between respective values of metal density for the first interconnect structure and the metal region.

3. The method of claim 1, wherein forming the guarding dummy structure includes forming a plurality of guarding dummy layers together with and corresponding to respective layers of the metal region and/or the first interconnect structure.

4. The method of claim 3, wherein one or more guarding dummy layers, of the plurality of guarding dummy layers, are oriented lengthwise perpendicular to a lengthwise direction of respective layers of the first interconnect structure.

5. The method of claim 4, wherein the one or more guarding dummy layers are oriented lengthwise perpendicular to a direction between the first interconnect structure and the metal region.

6. The method of claim 4, wherein the one or more guarding dummy layers are oriented lengthwise parallel to a direction between the first interconnect structure and the metal region.

7. The method of claim 3, wherein one or more guarding dummy layers, of the plurality of guarding dummy layers, are oriented lengthwise parallel to a lengthwise direction of respective layers of the first interconnect structure.

8. The method of claim 7, wherein the one or more guarding dummy layers are oriented lengthwise perpendicular to a direction between the first interconnect structure and the metal region.

9. The method of claim 7, wherein the one or more guarding dummy layers are oriented lengthwise parallel to a direction between the first interconnect structure and the metal region.

10. The method of claim 3, wherein one or more alternating guarding dummy layers, of the plurality of guarding dummy layers, are oriented lengthwise perpendicular to each other.

11. The method of claim 10, wherein the one or more alternating guarding dummy layers are oriented lengthwise perpendicular to respective layers of the first interconnect structure.

12. The method of claim 1, wherein, when the device is formed on a die:
the first interconnect structure is associated with a logic circuit of an interior portion of the die;
the metal region is associated with a periphery circuit of a periphery of the die; and
the guarding dummy structure defines a ring that is between the interior portion and the periphery.

13. The method of claim 12, wherein the periphery circuit includes at least one of an input-output (IO) circuit, an electrostatic discharge (ESD) protector circuit, a metal-oxide-metal (MOM) capacitor, or an electronic fuse (e-Fuse).

14. A semiconductor device structure, comprising:
a device layer disposed over a front-side of a substrate;
a front-side interconnect layer disposed over the device layer, the front-side interconnect layer including:
a first interconnect structure,
a metal region, and
a guarding dummy structure laterally between the first interconnect structure and the metal region;
a first dielectric layer disposed over the front-side interconnect layer;
one or more back-side vias coupled with the device layer opposite the front-side interconnect layer;
a second interconnect structure disposed over the device layer and the one or more back-side vias; and
one or more conductive features disposed over the second interconnect structure.

15. The semiconductor device structure of claim 14, wherein the guarding dummy structure is formed from copper, silver, gold, tungsten, aluminum, or combinations thereof.

16. The semiconductor device structure of claim 14, wherein the first interconnect structure has a lower metal density compared to the guarding dummy structure and the metal region.

17. The semiconductor device structure of claim 14, wherein a metal density of the guarding dummy structure is between respective values of metal density for the first interconnect structure and the metal region.

18. The semiconductor device structure of claim 14, wherein a metal density of the first interconnect structure is between 20% and 40% a metal density of the guarding dummy structure is between 40% and 60%, and a metal density of the metal region is between 60% and 80%.

19. A method of forming a back-side power rail device, comprising:
forming a device layer over a front-side of a substrate;
forming a first interconnect layer over the device layer, the first interconnect layer including:
a first interconnect structure,
a metal region, and
a guarding dummy structure laterally between the first interconnect structure and the metal region, wherein forming the guarding dummy structure includes forming a plurality of guarding dummy layers together with and corresponding to respective layers of the metal region and the first interconnect structure, wherein the guarding dummy structure is configured to balance a tensile stress of the metal region;
forming a first dielectric layer over the first interconnect layer;
removing, from a back-side of the substrate, at least a portion of the substrate to expose the device layer;
forming one or more back-side vias coupled with the device layer opposite the first interconnect layer; and
forming a second interconnect structure over the device layer and the one or more back-side vias to be coupled with a back-side power rail.

20. The method of claim 19, further comprising performing a dicing process on the back-side power rail device to form a plurality of dies, wherein:
the first interconnect structure is associated with a logic circuit of an interior portion of a die of the plurality of dies;
the metal region is associated with a periphery circuit of a periphery of the die; and
the guarding dummy structure defines a ring that is between the interior portion and the periphery.
